(19) United States
(12) Patent Application Publication
(10) Pub. No.: US 2024/0300807 A1
(43) Pub. Date: Sep. 12, 2024

(54) MICROMECHANICAL COMPONENT

(71) Applicant: Robert Bosch GmbH, Stuttgart (DE)

(72) Inventors: Jan Stiedl, Pliezhausen (DE); Tobias Henn, Stuttgart (DE)

(21) Appl. No.: 18/434,357

(22) Filed: Feb. 6, 2024

(30) Foreign Application Priority Data
Mar. 6, 2023 (DE) 10 2023 201 988.4

(51) Int. Cl. B81B 7/00; B81C 1/00; H01L 23/00

(52) U.S. Cl. CPC B81B 7/008; B81C 1/00238; H01L 24/32; H01L 24/48; H01L 24/73; H01L 24/83; H01L 2224/32225; H01L 2224/48227; H01L 2224/73215; H01L 2224/73265; H01L 2224/83; H01L 2224/85; H01L 2224/92147; H01L 2224/92247

(57) ABSTRACT

A micromechanical component having a printed circuit board with a main extension plane, having an ASIC chip and a MEMS chip, which are arranged parallel to the main extension plane, wherein the ASIC chip is arranged above the printed circuit board, and the MEMS chip is arranged above the ASIC chip, wherein the ASIC chip is electrically contacted to the printed circuit board in a bonding region by bonding wires. An adapter chip is arranged between the ASIC chip and the MEMS chip, which adapter chip at least partially covers the bonding region in a z-direction perpendicular to the main extension plane. A method for producing a micromechanical component is also described.

### CROSS REFERENCE

The present application claims the benefit under 35 U.S.C. § 119 of German Patent Application No. DE 10 2023 201 988.4 filed on Mar. 6, 2023, which is expressly incorporated herein by reference in its entirety.

### FIELD

The present invention relates to a micromechanical component having a printed circuit board with a main extension plane (x, y), having an ASIC chip and a MEMS chip, which are arranged parallel to the main extension plane, wherein the ASIC chip is arranged above the printed circuit board, and the MEMS chip is arranged above the ASIC chip, wherein the ASIC chip is electrically contacted to the printed circuit board in a bonding region by means of bonding wires.

### BACKGROUND INFORMATION

In order to be able to realize the trend of increasingly smaller MEMS sensor housings, a chip-on-chip design solution is necessarily used. Applying a MEMS chip directly to the ASIC results in a large number of requirements for the geometry and design of the respective chips. In addition to appropriate internal wiring of the chips with respect to one another in order to prevent crosswise bonding, the type, location and size of the respective bond pads, in particular on the ASIC, must also be taken into account in the design. This can be taken into account quite easily in a complete redevelopment of the AVT concept and the respective chips, but is usually reflected in the size of the chips. A small MEMS chip is mounted on a large ASIC chip. In many cases, however, already existing ASIC chips are to be reused for new components. As a result, the size and shape of the MEMS chip is already severely limited by the design of the ASIC or already excluded from the outset. In addition to the pure dimensions of the ASIC or MEMS chip, the form of the connection of the MEMS chip to the ASIC also plays an important role. In many cases, a very soft adhesive in conjunction with a thick adhesive layer must be used to attach the MEMS to the ASIC. Most adhesives used in this context are liquid and therefore run during the joining process. This running must additionally be taken into account when laying out the design.

The requirement to electrically connect the bond pads located on the surface of the ASIC to the substrate and to the MEMS chip results in dead zones on the ASIC that may be covered neither by the MEMS adhesive nor by the MEMS chip itself. The conventional MEMS sensor adhesives also show a tendency to bleed out. This bleeding behavior jeopardizes the reliability of the bonding connection on the ASIC. Therefore, the region to be kept free for the bonding must be increased further by a safety zone.

### SUMMARY

It is an object of the present invention to provide a micromechanical device and an associated production method that enable an ASIC chip and a MEMS chip of different sizes to be stacked securely on one another in a package.

The present invention proceeds from a micromechanical component having a printed circuit board with a main extension plane (x, y), having an ASIC chip and a MEMS chip, which are arranged parallel to the main extension plane, wherein the ASIC chip is arranged above the printed circuit board, and the MEMS chip is arranged above the ASIC chip, wherein the ASIC chip is electrically contacted in a bonding region by means of bonding wires.

According to the present invention, an adapter chip is arranged between the ASIC chip and the MEMS chip, which adapter chip at least partially covers the bonding region in a z-direction perpendicular to the main extension plane.

To achieve a sufficiently large zone to attach the MEMS sensor, the ASIC is partially or completely covered with a suitable “intermediate chip”, the adapter chip, which provides the necessary sufficiently large support surface for the MEMS chip and at the same time prevents the MEMS sensor adhesive from overflowing or bleeding to critical ASIC structures, in particular a bonding region. Suitable materials for the intermediate chip are, for example, silicon chips or glass chips, but the present invention is not limited to these materials.

The present invention makes it possible to realize a package with a smaller footprint for the combination of ASIC and MEMS chips that are geometrically incompatible for a traditional chip stack corresponding to FIGS. 1A and 1B, in comparison with the footprint that would be required for an arrangement of MEMS chip and ASIC chip next to one another on a contacting substrate, namely the printed circuit board for external contacting of the micromechanical component.

For the production of the arrangement according to the present invention, only established standard materials and methods from construction and connection technology are used. These are silicon wafers or glass wafers, back-thinning of the wafers by grinding, separating the chips by mechanical sawing, and mounting of the chips with FOW or FOD with standard die attach processes.

The proposed materials for the adapter chip, in particular silicon and glass, form a sufficiently large zone for the application of larger MEMS sensors, without the arrangement of the bond pads on the ASIC having to be changed. The adapter chip enables the partial stacking of the MEMS on the ASIC and the associated footprint minimization.

The mounting of the plateau materials by a FOW or FOD prevents the MEMS sensor adhesive from bleeding onto the exposed bond pads of the ASIC, since the sharp edge of the adapter chip acts as a stop edge. The footprint of the package can thereby be reduced further.

The attachment of the adapter chips with industrial standard die attach systems is extremely efficient. With a single system, >1000 sensors/h can be manufactured.

### BRIEF DESCRIPTION OF THE DRAWINGS

FIGS. 1A and 1B schematically show a micromechanical component of the related art in a side view and a plan view.

FIGS. 2A and 2B schematically show a micromechanical component according to an example embodiment of the present invention in a side view and a plan view.

FIG. 3 schematically shows a method according to an example embodiment of the present invention for producing a micromechanical component.

### DETAILED DESCRIPTION OF EXAMPLE EMBODIMENTS

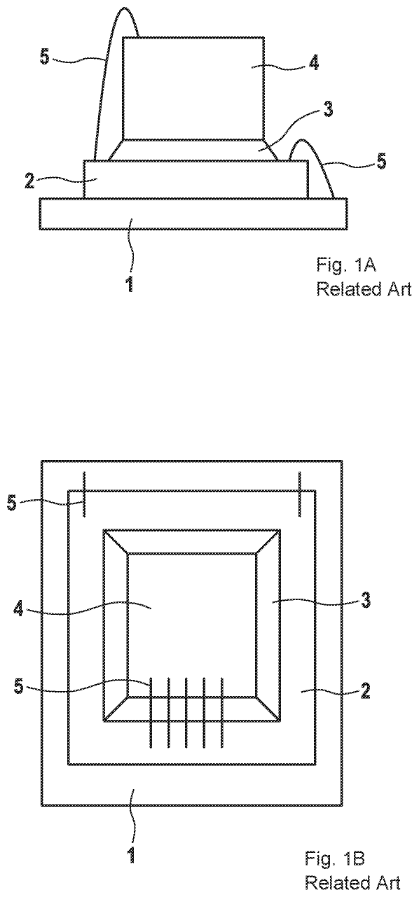

FIGS. 1A and 1B schematically show a micromechanical component in a side view and a plan view from the related art.

A typical structure of a MEMS sensor with chip-on-chip design is shown. An ASIC 2 is glued onto a printed circuit board 1, a contacting substrate such as a BGA or LGA, and electrically connected to the substrate by bonding wires 5. A MEMS sensor 4 is then glued onto the ASIC 2 using a soft adhesive having a thick adhesive layer 3. Finally, the MEMS sensor 4 is connected by means of bonding wires 5 to the ASIC 2 or to the substrate 1.

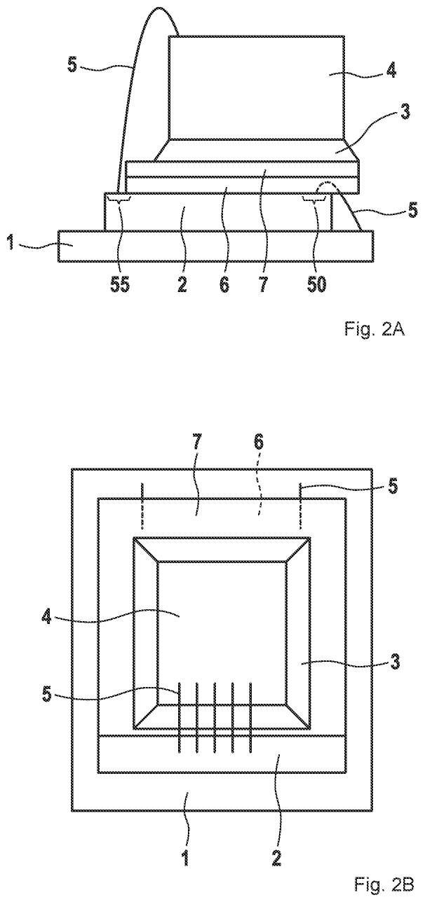

FIGS. 2A and 2B schematically show a micromechanical component according to the present invention in a side view and a plan view. The device largely corresponds to the related art component according to FIGS. 1A and 1B. On a printed circuit board 1 having a main extension plane (x, y), an ASIC chip 2 and a MEMS chip 4 are arranged parallel to the main extension plane. The ASIC chip is arranged above the printed circuit board and the MEMS chip is arranged above the ASIC chip. The ASIC chip is electrically contacted to the printed circuit board in a bonding region 50 by means of bonding wires 5. In a further bonding region 55, the ASIC chip is electrically contacted to the MEMS chip by means of bonding wires 5. According to the present invention, an adapter chip 7 is arranged between the ASIC chip and the MEMS chip, which adapter chip at least partially covers the bonding region 50 in a z-direction perpendicular to the main extension plane.

The adapter chip 7 is best manufactured from a suitable material, such as silicon or glass. It is mounted onto the ASIC chip using an adhesive film 6 such as film-over-wire (FOW) or film-over-die (FOD). The adapter chip 7 acts both as a plateau for enlarging the mounting surface for the MEMS chip 4 and as protection for the bond pads in the bonding region 50 on the ASIC chip 2 against possible bleeding of the MEMS sensor adhesive.

The adapter chip is thus an intermediate chip that is arranged between the ASIC chip and the MEMS chip. The intermediate chips are for example sawn out of wafers, which are ground back to the corresponding target thickness beforehand. In the arrangement described here, the intermediate chips are glued by means of “film-over-wire” (FOW) or “film-over-die” (FOD) onto the ASIC chip according to the ASIC wire bonding process, and the FOW or FOD is cured thermally. Subsequently, the sensors the sensor mounting are completed as in a standard process flow without further modifications to the manufacturing process.

To produce the proposed arrangement, it is best to mount the adapter chip onto the ASIC chip using FOW or FOD. In this case, the adapter chip can be applied by a simple force-time-controlled attachment process.

Alternatively, however, there is also the possibility of mounting the adapter chip on the ASIC chip using liquid adhesives. This possibility can be used, for example, if no FOW or FOD is currently available from a supplier for logistical reasons, or if they cannot be used for other reasons due to product-specific requirements. However, the disadvantage of this approach is that the adapter chip must be mounted on the ASIC chip with precise height control in order to avoid damaging the bonding wires emanating from the bonding region of the ASIC chip.

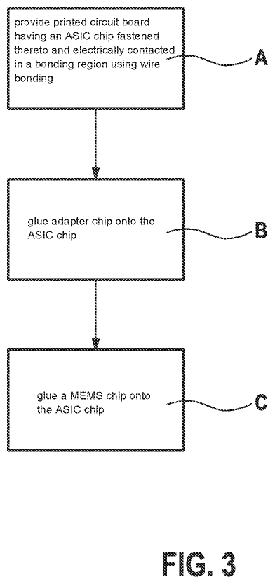

FIG. 3 schematically shows a method according to the present invention for producing a micromechanical component.

The method comprises the essential steps:
(A) providing a printed circuit board having an ASIC chip fastened thereto and electrically contacted in a bonding region by means of wire bonding;
(B) gluing an adapter chip onto the ASIC chip, wherein the adapter chip at least partially covers the bonding region;
(C) gluing a MEMS chip onto the adapter chip.

In step (B), the adapter chip is glued onto the ASIC chip with an adhesive, in the best case using FOD, FOW, or a liquid adhesive.

Furthermore, in a step (D) after step (C), the MEMS chip can be electrically contacted to the ASIC chip by means of wire bonding, wherein the ASIC chip is contacted in a further bonding region.

For most available ASIC technologies, the bond pads form a weak point in terms of corrosion resistance. In particular in the case of open package solutions without resistance, corrosive media can get onto the ASIC surface and lead to corrosion there. Thanks to the proposed arrangement, the bond pads lying below the FOW or FOD are better protected from corrosion because the diffusion rate of halogen ions in aqueous solution is significantly below the speed in air.

### LIST OF REFERENCE SIGNS

1 Printed circuit board
2 ASIC chip
3 Thick adhesive
4 MEMS chip
5 Bonding wires
6 Adhesive film (FOW or FOD)
7 Adapter chip
50 Bonding region
55 Further bonding region

What is claimed is:

1. A micromechanical component, comprising:
a printed circuit board with a main extension plane; and
an ASIC chip and a MEMS chip, which are arranged parallel to the main extension plane, wherein the ASIC chip is arranged above the printed circuit board, and the MEMS chip is arranged above the ASIC chip, wherein the ASIC chip is electrically contacted to the printed circuit board in a bonding region by bonding wires; and
an adapter chip arranged between the ASIC chip and the MEMS chip, the adapter chip at least partially covering the bonding region in a z-direction perpendicular to the main extension plane.

2. The micromechanical component according to claim 1, wherein the adapter chip is made of silicon or glass.

3. The micromechanical component according to claim 1, wherein the adapter chip is glued onto the ASIC chip using an adhesive, the adhesive being film-over-die (FOD) or film-over-wire (FOW) or a liquid adhesive.

4. The micromechanical component according to claim 1, wherein ASIC chip is electrically contacted to the MEMS chip in a further bonding region by bonding wires.

5. A method for producing a micromechanical component, comprising the following steps:
(A) providing a printed circuit board having an ASIC chip fastened thereto and electrically contacted in a bonding region by wire bonding;
(B) gluing an adapter chip onto the ASIC chip, wherein the adapter chip at least partially covers the bonding region;
(C) gluing a MEMS chip onto the adapter chip.

6. The method for producing a micromechanical component according to claim 5, wherein, in step (B), the adapter chip is glued onto the ASIC chip using an adhesive, the adhesive being film-over-die (FOD) or film-over-wire (FOW) or a liquid adhesive.

7. The method for producing a micromechanical component according to claim 5, wherein, in a step (D) after step (C), the MEMS chip is electrically contacted to the ASIC chip by wire bonding, wherein the ASIC chip is contacted in a further bonding region.
